(19) United States
(12) Patent Application Publication
(10) Pub. No.: US 2012/0273172 A1
(43) Pub. Date: Nov. 1, 2012

(54) HEAT DISSIPATION DEVICE

(75) Inventors: XIANG CAO, Shenzhen (CN); HAI-QING ZHOU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/160,515

(22) Filed: Jun. 15, 2011

(30) Foreign Application Priority Data
Apr. 28, 2011 (CN) 201110108131.8

(51) Int. Cl. H01L 23/467

(52) U.S. Cl. 165/121

(57) ABSTRACT

A heat dissipation device for a computer case is positioned over a hole of the computer case. The heat dissipation device includes a fan, two motors, two plates, and a controller. The fan is fixed in the computer case, and covers the hole. The two motors are positioned at two opposite sides of the fan. Each motor has a motor shaft parallel to a fan shaft of the fan. The two plates are respectively fixed on the two motor shafts. A distance between the two plates along the direction parallel to the motor rotor is greater than or equal to the thickness of the board. A controller is electrically connected to the fan and the two motors. The controller controls the two motors rotate the two boards for exposing or blocking the hole as the fan is on or off.

### BACKGROUND

1. Technical Field

The present disclosure relates to a heat dissipation device.

2. Description of Related Art

One common heat dissipation device for computers is a fan. The fan is fixed to a side wall of the computer case, in alignment with a hole defined in the side wall. However, when the fan stops, dust enters the fan through the hole, thereby adversely affecting the performance and working life of the fan.

What is needed, therefore, is a heat dissipation device capable of overcoming the described limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments.

FIG. 1 is a schematic view of a heat dissipation device, together with a computer case according to an embodiment.

FIG. 2 is a schematic view of a heat dissipation module of the heat dissipation device of FIG. 1.

FIG. 3 is a schematic view of the heat dissipation device of FIG. 1 in an open state.

FIG. 4 is a schematic view of the heat dissipation device of FIG. 1 in a closed state.

FIG. 5 is a schematic view of a control module of the heat dissipation device of FIG. 1.

FIG. 6 is a schematic view of a motor driving circuit of the control module of FIG. 5.

### DETAILED DESCRIPTION

Embodiments of the present disclosure are described in detail as follows, with reference to the accompanying drawings.

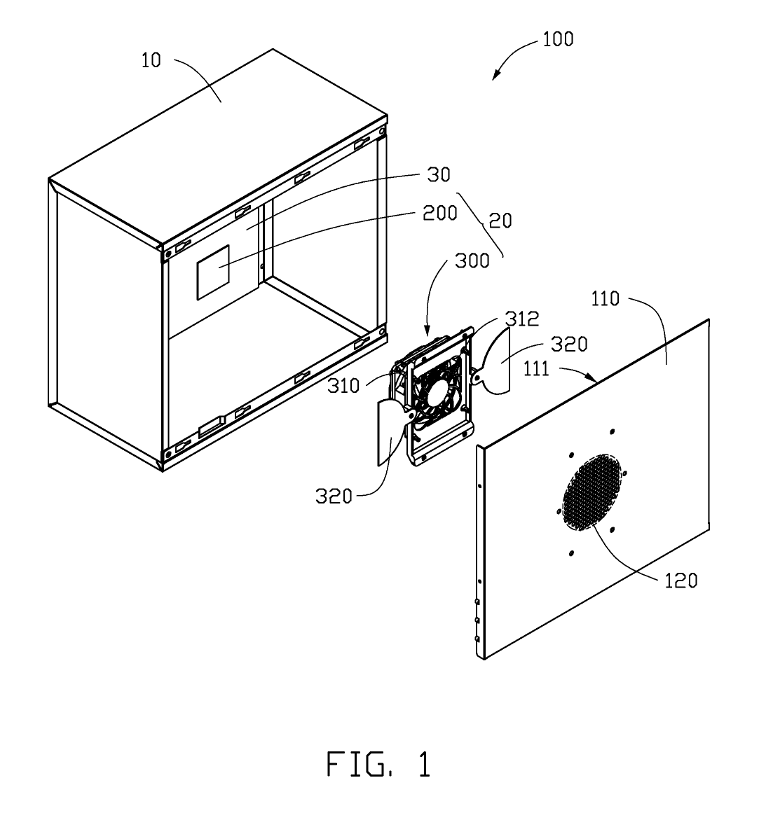

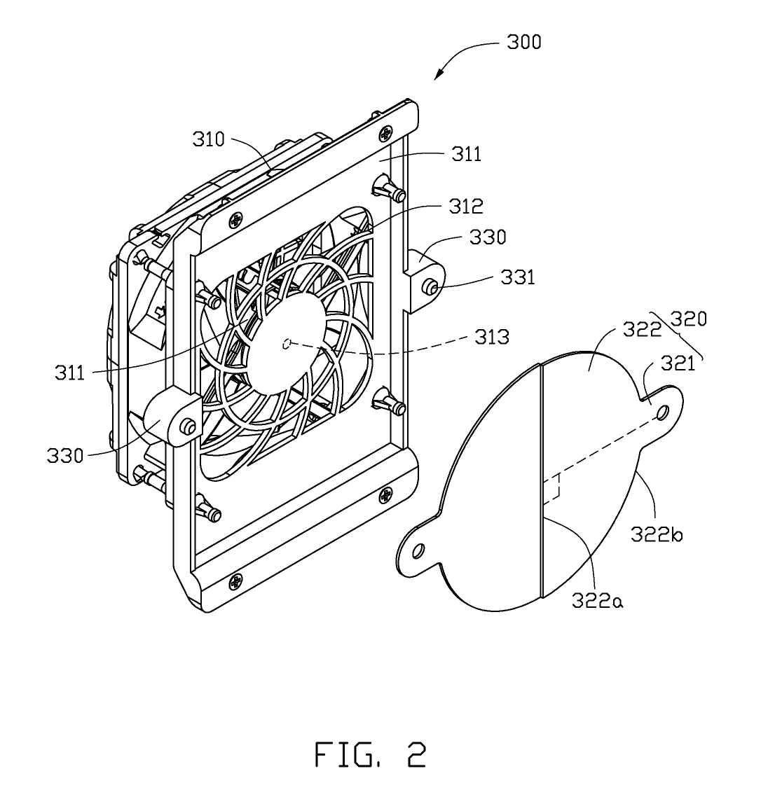

Referring to FIGS. 1 and 2, a computer case 100 according to an embodiment is shown. The computer case 100 includes a case 10, a heat dissipation device 20 fixed in the case 10, and a circuit board 30 fixed in the case 10. A side wall 110 of the case 10 defines a circular hole 120. A filter is mounted in the hole 120.

The heat dissipation device 20 includes a control module 200 and a heat dissipation module 300. The control module 200 is fixed on the circuit board 30. The heat dissipation module 300 is fixed against the inner surface 111 of the side wall 110, and faces the hole 120.

The heat dissipation module 300 includes a fan 310, two plates 320, and two motors 330. The fan 310 is fixed on the inner surface 111 by a base 311 of the fan 310. The base 311 defines a vent 312, with a substantially rectangular hole configuration, to face the hole 120.

The two motors 330 are disposed at the two opposite sides of the fan 310. The two motors 330 respectively drive the two plates 320 rotate simultaneously. In the present embodiment, both the two motors 330 are stepper motors. Each motor 330 includes a motor shaft 331 parallel to a fan shaft 313 of the fan 310. The motor shafts 331 and the fan shaft 313 are substantially on the same plane.

The two plates 320 are positioned between the base 311 and the side wall 110. The two plates 320 are respectively fixed on the two motor shafts 331 parallel to each other. In the present embodiment, the plates 320 as mounted on the motor shaft 331 are not coplanar, the perpendicular distance between the two planes 320 being equal to or greater than the thickness of one of the plates 320. The plate 320 includes a rotating portion 321 and a blocking portion 322. The rotating portion 321 is fixed on the motor shaft 331. The blocking portion 322 blocks approximately one half of the hole 120. In the present embodiment, the blocking portion 322 is a semicircle. The diameter of the blocking portion 322 is at least equal to that of the hole 120. The two blocking portions 322 effectively form a circle to block the hole 120 and prevent dust from entering the fan 310. The blocking portion 322 includes a straight line portion 322a and an arc portion 322b. The rotating portion 321 is integral with the arc portion 322b. The rotating portion 321 is positioned on a perpendicular line from the middle of the straight line portion 322a.

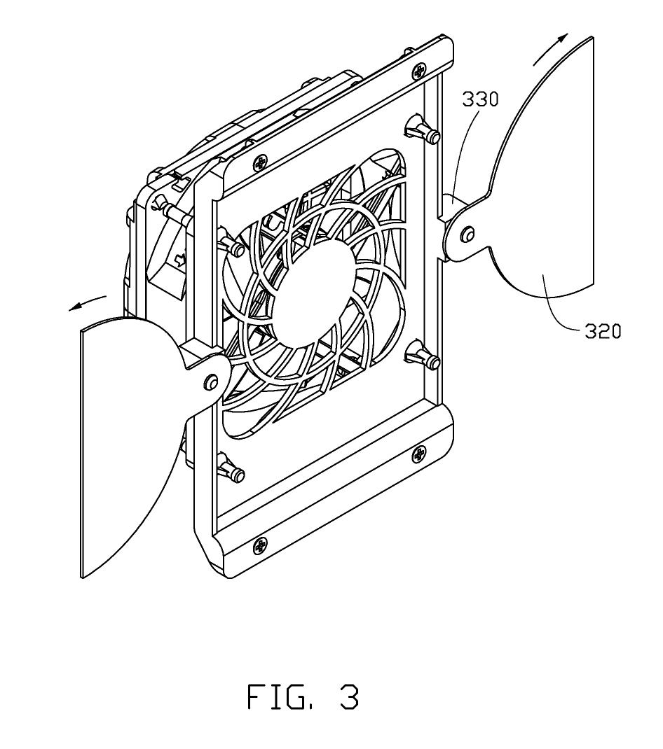

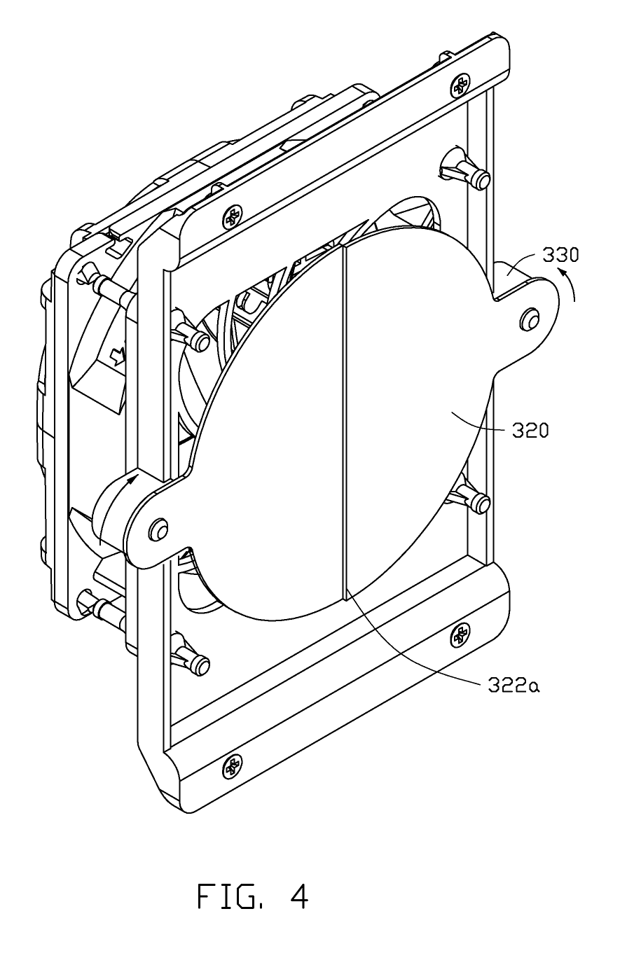

Referring to FIGS. 3 and 4, when the two motors 330 rotate the two plates 320 away from each other, the vent 312 is exposed to the hole 120. When the two motors 330 rotate the two plates 320 back towards each other until the two straight line portions 322a meet or coincide with each other, the vent 312 is blocked to prevent dust from entering the fan 310.

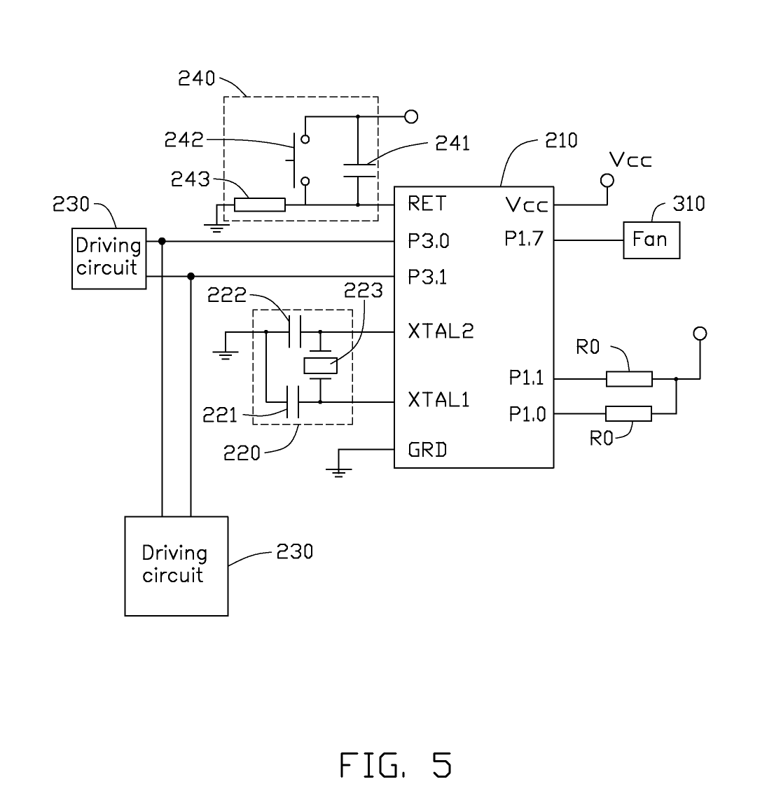

Referring to FIG. 5, the control module 200 includes a controller 210, a crystal oscillator circuit 220, two driving circuits 230, and a reset circuit 240. The crystal oscillator circuit 220, the two driving circuits 230, and the reset circuit 240 are all electrically connected to the controller 210.

In the present embodiment, the controller 210 is a type 89C2051 microcontroller. A VCC terminal of the controller 210 is electrically connected to a voltage source VCC. A P1.7 terminal of the controller 210 is electrically connected to the fan 310 to receive a power on signal or a power off signal of the fan 310. A P1.1 terminal and a P1.0 terminal of the controller 210 are each electrically connected to a pull-up resistor (two pull-up resistors R0). A GRD terminal of the controller 210 is grounded.

An XTAL1 terminal and an XTAL2 terminal of the controller 210 are electrically connected to the crystal oscillator circuit 220. The crystal oscillator circuit 220 includes two capacitors 221 and 222, and a crystal oscillator 223. The XTAL1 terminal of the controller 210 is electrically connected to an end of the capacitor 221 and an end of the crystal oscillator 223. The XTAL2 terminal of the controller 210 is electrically connected to the opposite end of the capacitor 222 and the opposite end of the crystal oscillator 223. The crystal oscillator 223 generates a clock frequency to the controller 210.

One driving circuit 230 is electrically connected to a P3.0 terminal and a P3.1 terminal of the controller 210. The other driving circuit 230 is electrically and reversely connected to the P3.0 terminal and the P3.1 terminal of the controller 210. The two driving circuits 230 are connected in parallel with each other. The controller 210 sends a control signal to the two driving circuits 230 simultaneously through the P3.0 terminal and the P3.1 terminal.

An RET terminal of the controller 210 is electrically connected to the reset circuit 240. The reset circuit 240 includes a capacitor 241, a switch 242 and a resistor 243. The RET terminal of controller 210 is electrically connected to an end of the capacitor 241, an end of the switch 242, and an end of the resistor 243. The opposite end of the capacitor 241 and the opposite end of the switch 242 is electrically connected to a voltage source VCC. The opposite end of the resistor 243 is grounded. When the switch 242 is closed, the controller 210 is reset. At the same time, both the P3.0 terminal and the P3.1 terminal of the controller 210 output a high level signal to the two driving circuits 230.

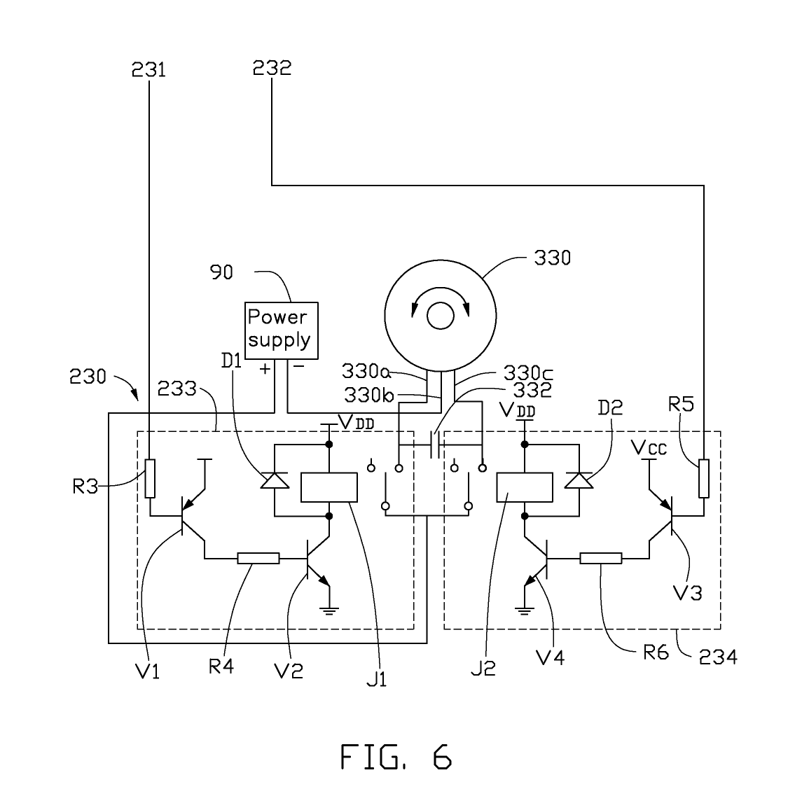

Referring FIG. 6, the two driving circuits 230 drive the two motors 330 simultaneously. The driving circuit 230 includes a first input terminal 231, a second input terminal 232, a first controlling branch circuit 233 and a second controlling branch circuit 234.

The first input terminal 231 is electrically connected to the P3.0 terminal of the controller 210. The first controlling branch circuit 233 includes a first resistor R3, a first transistor V1, a second resistor R4, a second transistor V2, a first relay J1 and a first diode D1 connected to the P3.0 terminal in order from the P3.0 to a voltage V_{DD}. The first resistor R3 is connected in series between the P3.0 terminal of the controller 210 and the base of the first transistor V1. The emitter of the first transistor V1 is electrically connected to the voltage source VCC. The collector of the first transistor V1 is electrically connected to an end of the second resistor R4. The other end of the second resistor R4 is electrically connected to the collector of the second transistor V2. The emitter of the second transistor V2 is grounded. The collector of the second transistor V2 is connected to the first relay J1. The relay J1 is connected to the second diode D1 in parallel. The first relay J1 is connected between a power supply 90 and the motor 330. In the present embodiment, the motor 330 includes a first binding post 330a, a second binding post 330b and a third binding post 330c. The first relay J1 is connected between an anode of the power supply 90 and the first binding post 330a of the motor 330. A cathode of the power supply 90 is connected to the second binding post 330b of the motor 330. A capacitor 332 is connected between the first binding post 330a and the third binding post 330c. The first relay J1 controls the connection of the first binding post 330a to the power supply 90 or the disconnection from the power supply 90 by a control signal from the first input terminal 231.

The second input terminal 232 is electrically connected to the P3.1 terminal of the controller 210. The second controlling branch circuit 234 includes a third resistor R5, a third transistor V3, a fourth resistor R6, a fourth transistor V4, a second relay J2 and a second diode D2 connected to the P3.1 terminal in order from the P3.1 terminal to a voltage V_{DD}. The connection method of the second controlling branch circuit 234 is similar to that method of the first controlling branch circuit 233. But the second relay J2 is connected between the anode of the power supply 90 and the third binding post 330c of the motor 330. The second relay J2 controls the third binding post 330c connect to the power supply 90 or disconnect from the power supply 90 by the control signal from the second input terminal 232.

The controller 210 pre-sets a number of revolutions. In the present embodiment, the number of revolutions is ½ of one revolution. In other embodiments, the number of revolutions can be ¼or ¾ of one revolution. When the P1.7 terminal of the controller 210 receives a power on signal from the fan 310, the controller 210 outputs a first signal by the P3.0 terminal. In the present embodiment, the first signal is a low level signal. When the first controlling branch circuit 233 receives the first signal, the first relay J1 makes the first binding post 330a of the two motor 330 connect to the power supply 90. The two motors 330 rotate the two plates 320 away from each other until the two motors 330 have rotated ½ of one revolution, the vent 312 is then completely exposed to the hole 120. When the P1.7 terminal of the controller 210 receives a power off signal of the fan 310, the controller 210 outputs a second signal via the P3.1 terminal In the present embodiment, the second signal is a low level signal same as the first signal. When the second controlling branch circuit 234 receives the second signal, the second relay J2 makes the third binding post 330c of the two motor 330 connect to the power supply 90. The two motors 330 rotate the two plates 320 towards each other until the two motors 330 have rotated ½ of one revolution and the two straight line portion 322a coincide with each other so the vent 312 is blocked by the two blocking portions 322. When the switch 242 is closed by a user, the P3.0 terminal and the P3.1 terminal both outputs the high level signal to stop the two motors 330.

While certain embodiments have been described and exemplified above, various other embodiments will be apparent to those skilled in the art from the foregoing disclosure. The present disclosure is not limited to the particular embodiments described and exemplified, and the embodiments are capable of considerable variation and modification without departure from the scope of the appended claims.

What is claimed is:

1. A heat dissipation device for a computer case having a hole defined in a side of the computer case, the heat dissipation device comprising:
a fan fixed in the computer case, covering the hole;
two motors positioned at two opposite sides of the fan, each motor having a motor shaft parallel to a fan shaft of the fan;
two plates respectively fixed on the two motor shafts, a distance between the two plates along the direction parallel to the motor shaft greater than or equal to the thickness of the plate;
a controller electrically connected to the fan and the two motors, wherein
the controller controls the two motors rotate the two plates for exposing or blocking the hole corresponding to the fan power on or power off.

2. The heat dissipation device as claimed in claim 1, wherein the plate comprises a rotating portion fixed on the motor shaft.

3. The heat dissipation device as claimed in claim 2, wherein the plate comprises a blocking portion connected to the rotating portion, the blocking portion is a semicircle.

4. The heat dissipation device as claimed in claim 3, wherein the diameter of the blocking portion is equal to that of the hole.

5. The heat dissipation device as claimed in claim 3, wherein the blocking portion comprises a straight line portion and an arc portion, the rotating portion is integral with the arc portion, the rotating portion is positioned on a perpendicular line from the middle of the straight line portion.

6. The heat dissipation device as claimed in claim 1, wherein the perpendicular distance between the two plates along the direction parallel to the motor shaft is equal to the thickness of the plate.

7. The heat dissipation device as claimed in claim 1, further comprising a driving circuit having a first controlling branch circuit and a second controlling branch, the first controlling branch circuit and the second controlling branch driving the two motors rotate in two opposite directions corresponding to the fan power on or power off.

8. The heat dissipation device as claimed in claim 1, wherein the interval between the soldering portion and the outer pin is 1 mm.

9. The heat dissipation device as claimed in claim 8, wherein each motor comprises a first binding post, a second binding post, and a third binding post, the second binding post is electrically connected to a cathode of a power supply, the first controlling branch circuit comprises a first relay connected between the first binding past and an anode of the power supply, when the first relay makes the first binding post of the two motor connect to the power supply, the first controlling branch circuit drives the motors rotate, when the second relay makes the third binding post of the two motor connect to the power supply, the second controlling branch circuit drives the motors rotate.

10. The heat dissipation device as claimed in claim 8, wherein when the controller receives a power on signal of the fan, the controller outputs a first signal to the first controlling branch circuit for driving the two motors rotate the two plates away from each other, when the controller receives a power off signal of the fan, the controller outputs a second signal to the second controlling branch circuit for driving the two motors rotate the two plates toward each other.

11. The heat dissipation device as claimed in claim 10, wherein the first signal and the second signal are both lower level signal.

12. The heat dissipation device as claimed in claim 11, further comprising a reset circuit electrically connected to the controller, and configured for controlling the controller output a high level signal to the first controlling branch circuit and the second controlling branch circuit.
